(19) United States
(12) Patent Application Publication
(10) Pub. No.: US 2017/0031239 A1
(43) Pub. Date: Feb. 2, 2017

(54) STRUCTURING OVER TOPOGRAPHY

(71) Applicant: Infineon Technologies AG, Neubiberg (DE)

(72) Inventors: Sebastian SCHMIDT, Munich (DE); Martina SEIDER-SCHMIDT, Munich (DE); Peter IRSIGLER, Obernberg/Inn (AT); Oliver HELLMUND, Neubiberg (DE)

(21) Appl. No.: 15/220,480

(22) Filed: Jul. 27, 2016

(30) Foreign Application Priority Data
Jul. 30, 2015 (DE) 102015112486.6

(51) Int. Cl. G03F 1/50; G03F 7/16; G03F 7/20; H01L 21/027

(52) U.S. Cl. CPC G03F 1/50; H01L 21/0274; G03F 7/16; G03F 7/20

(57) ABSTRACT

In various embodiments, a reticle is provided. The reticle may include a feature. The feature may include a base structure, and a step structure. The a step structure includes a center region and an edge region. The center region includes, in a top view, a larger width than the edge region. The step structure is configured to be arranged over a topography step of a substrate to be lithographically processed.

### CROSS-REFERENCE TO RELATED APPLICATION

This application claims priority to German Patent Application Serial No. 10 2015 112 486.6, which was filed Jul. 30, 2015, and is incorporated herein by reference in its entirety.

### TECHNICAL FIELD

Various embodiments relate generally to a method for processing a semiconductor device. Furthermore, various embodiments relate to a method for improving the quality of lithography processes.

### BACKGROUND

Fabrication of integrated circuits (ICs) involves the formation of features on a substrate that make up circuit components, such as transistors, resistors and capacitors.

Semiconductor manufacturing variations can be classified as process systematic and random variations. Systematic variations are predictable in nature and depending on deterministic factors such as layout structure and surrounding topological environment.

The current technology is able to transfer a pattern of a reticle to a photoresist with high fidelity. However, due to the aforementioned factors, the photoresist does not often reproduce the transferred pattern with high fidelity after being developed in solutions.

For example, the developed photoresist may exhibit the pinching effect when the underlying structure to be processed (e.g., polyline, metallization etc.) is not planar. If the pinching of the photoresist is being transferred to the underlying structure to be processed, it may lead to performance deterioration and reliability deterioration of the device.

Therefore, there is a need for an improved process that addresses the above-mentioned challenges.

### SUMMARY

Embodiments generally relate to semiconductor devices. In one embodiments, to a reticle is disclosed. The reticle includes a base structure and a step structure. The step structure includes a center region and an edge region. The center region includes, in a top view, a larger width than the edge region. The step structure is configured to be arranged over a topography step of a substrate to be lithographically processed.

In another embodiment, a method of manufacturing a device is disclosed. The method includes depositing a resist layer over a substrate having at least one topography step. The method also includes exposing at least a portion of the resist layer using a reticle. The reticle includes a base structure and a step structure. The step structure includes a center region and an edge region. The center region includes, in a top view, a larger width than the edge region. The step structure is configured to be arranged over a topography step of a substrate to be lithographically processed. The method also includes removing a portion of the resist layer in accordance with the exposure.

In yet another embodiment, a method of manufacturing a reticle is disclosed. The method includes forming a plurality of plurality of test structures on a test reticle, each of the test structures including a step structure having a center region and an edge region. The center region includes, in a top view, a larger width than the edge region. The step structure is configured to be arranged over a topography step of a substrate to be lithographically processed. The method also includes forming a plurality of lithographically processed structures on a test substrate having a plurality of topography steps, each lithographically processed structure being formed over a respective topography step of the plurality of topography steps using a respective test structure of the test reticle. The method also includes selecting at least one of the test structures from the plurality of test structures and forming a reticle having a step structure in accordance with the selected test structure.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows an exemplary optical lithography system;

FIG. 2 shows a scanning electron microscope (SEM) image of a partially processed device;

FIG. 3 shows an exemplary plan view of a feature of a reticle, an exemplary plan view of a partially processed device and an exemplary cross-sectional view of the partially processed device;

FIG. 4 shows an exemplary plan view of a feature of a reticle, an exemplary plan view of a partially processed device and an exemplary cross-sectional view of the partially processed device;

FIG. 5 shows an exemplary flow chart diagram 500 of a method of manufacturing a device; and

FIG. 6 shows an exemplary flow chart diagram 600 of a method of manufacturing a reticle.

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical and electrical changes may be made without departing from the scope of the invention. The various embodiments are not mutually exclusive, as some embodiments can be combined with one or more other embodiments to form new embodiments. The following detailed description therefore is not to be taken in a limiting sense, and the scope of the present invention is defined by the appended claims.

Various embodiments are provided for methods, and various embodiments are provided for devices. It will be understood that basic properties of the methods also hold for the devices and vice versa. Therefore, for the sake of brevity, duplicate description of such properties may be omitted.

The term “at least one” as used herein may be understood to include any integer number equal to or greater than one, i.e., “one”, “two”, “three”, . . . etc.

The term “a plurality” as used herein may be understood to include any integer number equal to or greater than two, i.e., “two”, “three”, “four”, . . . etc.

Unless otherwise stated, the term “layer” as used herein may be understood to include embodiments where a layer is a single layer, as well as embodiments where a layer is a layer stack including a plurality of sublayers.

The word “exemplary” is used herein to mean “serving as an example, instance or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g., in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

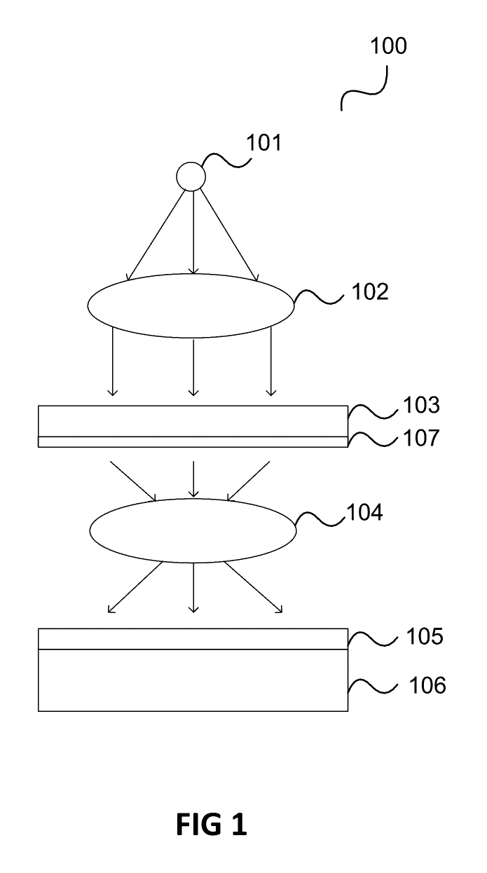

FIG. 1 shows an exemplary optical lithography system 100. For purposes of illustration, the exemplary lithography system 100 as shown is simplified. For instance, well-known features are omitted or simplified to clarify the description of the exemplary implementations and embodiments of the present disclosure, and to thereby better explain the exemplary implementations and embodiments.

The optical lithography system 100 as shown in FIG. 1 utilizes the projection printing method. It will be appreciated that other exposure methods, e.g., contact printing or proximity printing, may be used to implement the teachings of the disclosure contained herein.

The optical lithography system 100 may include a light source 101, a condenser lens 102, a reticle (or mask) 103, a projection (or reduction) lens 104 and a substrate 106. A top surface of the substrate 106 may be coated with a photoresist 105. It will be understood that the terms “reticle” and “mask” are used interchangeably herein.

The light source 101 illuminates light onto the substrate 106. The illuminated light transmits through the condenser lens 102, diffracts by the reticle 103 and the diffraction pattern of the light is picked up by the projection lens 104. As a result, an image of a pattern 107 on the reticle 103 is projected onto the resist-coated substrate 106, which is disposed at a distance from the reticle 103.

In various embodiments, the substrate 106 may, for example, be a semiconductor substrate, such as a silicon substrate. Other type of substrates, for example, SiGe, SiGeC or SiC, may also be used. In various embodiments, the substrate 110 may be a crystalline-on-insulator (COI), such as a silicon-on-insulator (SOI) substrate. Other types of COI substrates may also be used. The substrate 110 may, for example, be a doped or undoped substrate.

The substrate 106 may, for example, be a substrate at different process stages of a semiconductor device, such as a semiconductor die of an IC. The IC may be any type of IC. In various embodiments, the IC may be memory devices such as a dynamic random access memory (DRAM), a static random access memory (SRAM) and various types of non-volatile memories including programmable read only memories (PROM) and flash memories, logic devices, communication devices, optoelectronic devices, digital signal processors (DSPs), microcontrollers, system-on-chips (SOCs) as well as other types of devices or a combination thereof. In various embodiments, the IC may be power ICs or power chips including power diodes, thyristors, power MOSFET, insulated gate bipolar transistors (IGBTs) as well as other types of devices or a combination thereof. Other types of ICs or devices may also be useful. The ICs can be incorporated into various products, such as phones, computers, personal digital assistants, automobiles or other types of suitable products.

The photoresist 105 may include a light sensitive material. There are two types of photoresist, namely the positive photoresist and negative photoresist. The positive photoresist may include a light sensitive material and a base resin. The negative photoresist material may include a light sensitive material and a polymer. Exposing the photoresist with a light source may change the solubility of the light sensitive material.

For a positive photoresist, exposure to a light source may change the chemical structure of the photoresist, so that it may become more soluble in the developer solution. The exposed photoresist may then be washed away by the developer solution, whereas the unexposed photoresist is retained on the substrate. The reticle used for a positive photoresist, therefore, contains an exact copy of the pattern which is to remain on the substrate.

The negative photoresist is the reverse of the positive photoresist. The exposed photoresist may be polymerized and hence it may become insoluble in the developer solution. The exposed photoresist may be retained on the substrate, whereas the unexposed photoresist may be washed away by the developer solution. Therefore, the reticle used for a negative photoresist contains an inverse copy of the pattern which is to remain on the substrate.

The photoresist 105 may be applied to a surface of the substrate 106 by a standard spin coating technique. Other techniques of coating the surface of the substrate may also be used.

In various embodiments, a device layer (not shown) may be provided between the photoresist and the substrate. The device layer may be etched using the developed photoresist. What remains of the etched device layer may be used as gates, isolation fields or as conducting pathways to carry signals.

The light source 101 may be a point source. In various embodiments, mercury (Hg) or mercury-Xenon (Hg—Xe) lamp may be used as the light source 101 in a visible and ultraviolet photolithography system. Other types of lamps may also be used as the light source 101, depending on the types and wavelengths of the optical lithography system. For example, excimer laser (e.g., argon (Ar), krypton (Kr), fluorine (F), chlorine (Cl) or a combination thereof) may also be used as the light source.

The reticle 103 may be a transparent substrate having a first major side and a second major side. The second major side is opposite the first major side. The transparent substrate may be a soda lime glass, a borosilicate glass, a quartz glass or any suitable transparent materials commonly used in semiconductor lithography system. One of the major sides of the substrate may include the pattern 107, e.g., a line, a dot, a square or a combination thereof. In various embodiments, the pattern 107 may be formed by a light blocking material, e.g., chromium, which is deposited on the substrate. the illuminated light from the light source is completely blocked by the light blocking material and fully transmitted through the unblocked substrate portions. This type of the reticle is called a binary mask. In various embodiments, the pattern 107 may be formed by etching one of the major sides of the substrate to specific depths that are dependent on the wavelength of the optical lithography system. For example, certain transmitting regions on one of the major sides of the substrate is etched to different depths to induce a phase shift in the light traveling through those regions of the reticle. This type of the reticle is called a phase shift mask. It is to be noted that also attenuated or half tone phase shift masks may be used in various embodiments.

The pattern 107 on the reticle may be larger than the final pattern of the photoresist. In such a case, the projection lens 104 provides a demagnification ratio of approximately 4 times. That is, the intended photoresist feature may be 4 times smaller than the corresponding feature of the reticle.

Ideally, the pattern of a developed photoresist reproduces the pattern of a reticle with high fidelity. However, interference of light reflected from the photoresist/substrate interface affects the line-width uniformity of a developed photoresist. The substrate (or a device layer disposed over the substrate) may reflect a portion of the light from a lithography light source and transmits the rest according to the refractive index at the specific wavelength used. The substrate reflectivity affects the effective amount of radiation energy being absorbed in the resist. A slight variation of resist thickness will result in a drastic change of the reflectivity and hence the final effective energy doses. Approaches such as providing a sacrificial anti-reflective coating (ARC) layer onto the substrate surface have been used to reduce or suppress the reflection from the substrate. The sacrificial ARC is removed after the resist is developed.

The application of the sacrificial ARC, however, does not prevent pinching effect of the developed photoresist, particularly when the substrate (or a device layer disposed over the substrate) has a laterally heterogeneous top surface. For example, the top surface of the substrate may include a topography step. In particular, the topography step is one of the common topography features for devices used in the power technologies due to missing global planarization steps (e.g., chemical mechanical polishing). Such topography step may be more significant in height, for example, in FINFET technologies which has especially smaller nodes as compared to MOSFET technologies. This is because global planarization steps cannot be made prior to structuring.

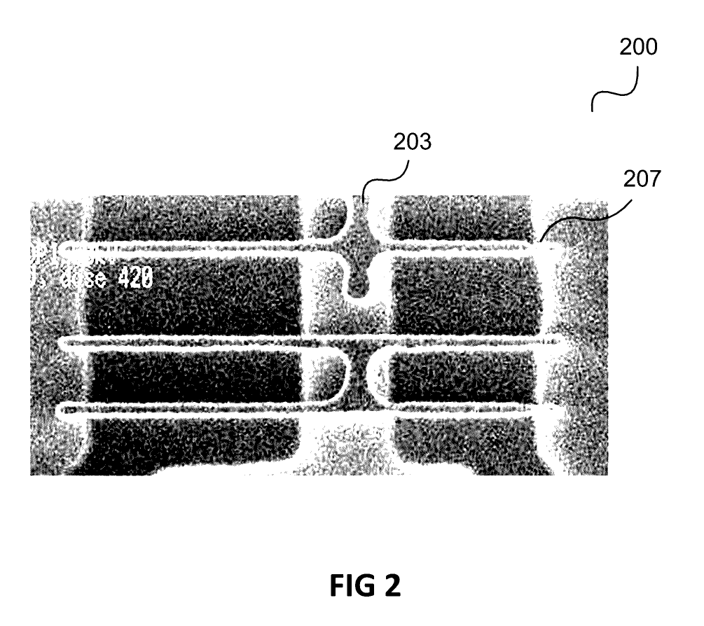

FIG. 2 shows a scanning electron microscope (SEM) image 200 of a partially processed device. The SEM images 200 shows an exemplary top view of the pinching effect of a polysilicon line 203 after being etched using a developed photoresist. Studies have shown that pinching tends to occur at the transition from a gate going from an active area to the wiring on a field oxide, where the surface topography is not flat. As shown in the SEM image, the polysilion line 203 traverses the top surface of a partially processed device and it is pinched at the sidewall of the field oxide 201 which has a step topography. The pinched portion 107 of the polysilicon line has a narrower linewidth as compared to the other portion of the polysilicon line that does not suffer from the pinching effect. The occurrence of pinching is due to the reflectivity from the polysilicon at the sidewall of the field oxide and different interference conditions attributed to a dramatically changed photoresist variation. Such pinching of the polysilicon line at the sidewall of the field oxide may lead to deterioration of the device performance and the deterioration may be severe for analog devices.

For purposes of illustration, the various embodiments are described in the context of pinching of polysilicon line. However, it should be noted such pinching is not limited to polysilicon lines, it may also occur for conducting pathways (e.g., metal lines) which carry signals and oxides.

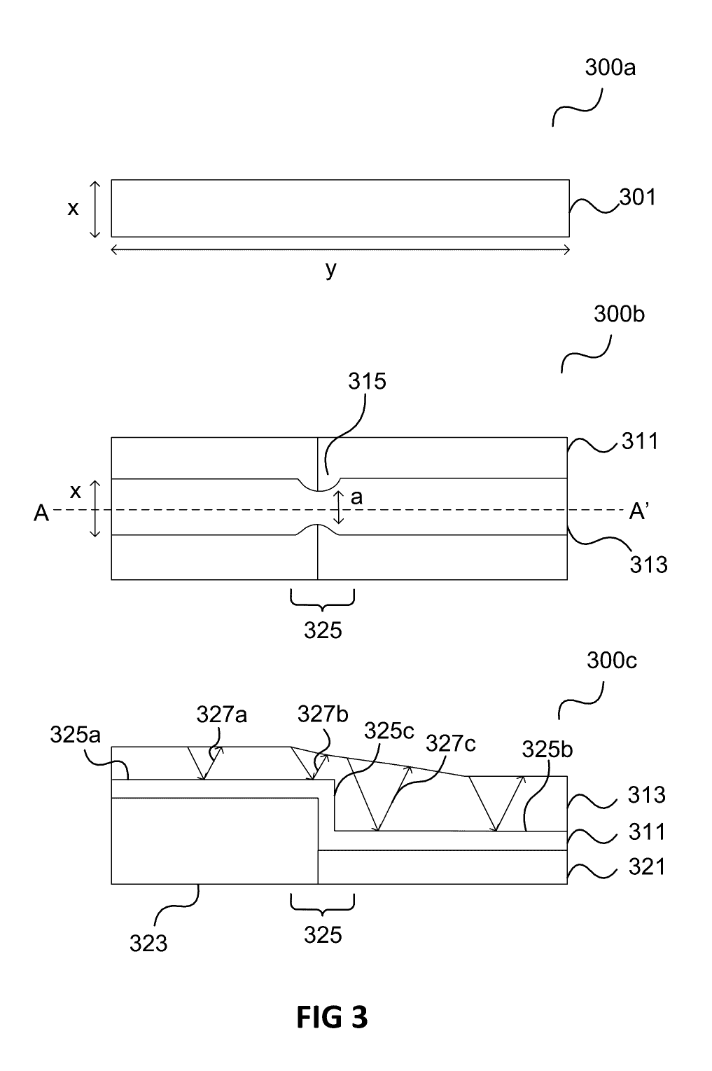

FIG. 3 shows an exemplary plan view 300a of a feature of a reticle, an exemplary plan view 300b of a partially processed device and an exemplary cross-sectional view 300c of the partially processed device.

The feature 301 may be one of the features of the pattern of a reticle. The feature 301 may be a rectangular having a uniform linewidth x along a length y, as seen in the plan view 300a. In other words, the feature may be a rectangular with a fixed linewidth x along a length y, as seen in the plan view 300a. The feature need not be a rectangular. It can be of any geometrical shapes. For the purpose of illustration, the various embodiments are described in the context of a line having a rectangular shape in a plan view. The feature 301 may be used to form a polysilicon line on a substrate 321.

The plan view 300b show a developed photoresist 313 of a partially processed device. The developed photoresist 313 corresponds to the feature 301. The cross-sectional view 300c is taken along line A-A′ of the plan view 300b. The partially processed device may include a substrate 321, a isolation structure 323, a polysilicon layer 311 and a photoresist layer 313. The isolation structure 323 may be a field oxide. In various embodiments, the field oxide may be a local oxidation of silicon (LOCOS). Other types of isolation structures may also be useful. In various embodiments, the isolation structure 323 may have a raised top surface. The raised top surface may protrude above a top surface of the substrate 321. The polysilicon layer 311 may be disposed over the isolation structure 323 and the substrate 321. In various embodiments, the polysilicon layer 311 may be a conformal layer. In other words, the polysilicon layer 311 may adopt the topography of the underlying substrate and/or layers. The photoresist layer 313 may be disposed over the polysilicon layer 311. In various embodiments, the photoresist layer 311 may be a developed photoresist. That is, the photoresist layer 311 may have been illuminated by a light source using the reticle having the feature 301 and developed in a developer solution.

The partially processed device may include a topography step 325. The topography step 325 may include a top surface 325a, a bottom surface 325b and an edge 325c formed therebetween. The top surface 325a and the bottom surface 325b may be located at different levels. In various embodiments, the top surface 325a and the edge 325c may form an angular or a curved shape.

The thickness variations of the photoresist layer 313 may affect the reflectivity of the surface. As shown in the cross-sectional view 300c of the partially processed device, the nominal reflectivity 327a occurs at a nominal photoresist thickness, which is less than the maximum thickness and more than the minimum thickness of the photoresist layer 313. The highest reflectivity 327b occurs at the minimum thickness of the photoresist layer 313 which coincides with the bend of the step topography, whereas the lowest reflectivity 327b occurs at the maximum thickness of the photoresist layer 313. Therefore, the minimum absorption of the illumination energy occurs at the minimum thickness of the photoresist layer 313 and the maximum absorption of the illumination energy occurs at the maximum thickness of the photoresist layer 313. Assuming the photoresist layer is a negative photoresist, the dissolution rate is therefore the highest at unexposed photoresist area. Since the photoresist layer 313 at the maximum thickness has the maximum adsorption as compared to the photoresist layer 313 at the minimum thickness, the photoresist layer 313 at the maximum thickness undergoes more cross-linking and it becomes more difficult to dissolve in the developer solution as compared to the photoresist layer 313 at the minimum thickness. As a result, a pinched area 315 may be present at the minimum thickness of the photoresist layer 313 due to a higher localized dissolution rate. Therefore, the fidelity of the developed photoresist 313 is of an inferior quality due to the presence of a pinched area 315.

As shown in the plan view 300b, the pinched area 315 of the developed photoresist 313 substantially coincides with the topography step 325 of the underlying surface. The photoresist 313 has a smaller linewidth at the pinched area 315 as compared to the linewidth which is further away from the topography step 325. The pinched area 315 may have a linewidth a which is smaller than the linewidth x of the feature 301 of the reticle. On the other hand, the linewidth of the photoresist which is further away from the topography step 325 may be substantially the same as the linewidth x of the feature 301 of the reticle.

Subsequent processing (e.g., etching of the polysilicon layer 311) using the developed photoresist 313 having a pinched area may result in a polysilicon line which adopts the shape and profile of the developed photoresist 313. That is, the pinched area, which potentially be detrimental to the device performance, may be transferred to the etched polysilicon layer 311.

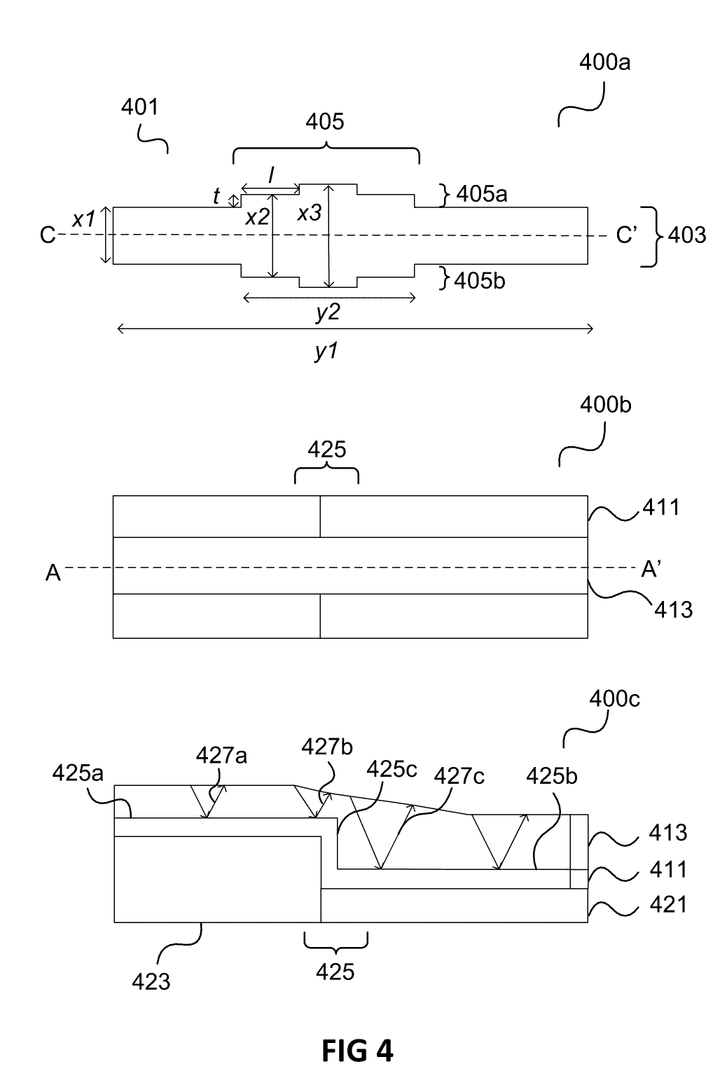

FIG. 4 shows an exemplary plan view 400a of a feature of a reticle, an exemplary plan view 400b of a partially processed device and an exemplary cross-sectional view 400c of the partially processed device. The partially processed device as shown in FIG. 4 may be identical to the partially processed device as shown in FIG. 3, except the linewidth and the shape profile of the developed photoresist layer.

The feature 401 may be one of the features of the pattern of a reticle. The feature 401 may have a step-like shape, as shown in the plan view 400a. The feature 401 may have a central axis C-C′ along a length y1. In various embodiment, the feature 401 may include a base structure 403 and a step structure 405. The base structure 403 may be a rectangular with a uniform linewidth x1 along the length y1, as shown in the plan view 400a. In other words, base structure 403 may be a rectangular with a fixed linewidth x1, as shown in the plan view 400a.

The step structure 405 may include a plurality of steps along a length y2, as shown in the plan view 400a. The step structure 405 may include a first step structure 405a having a plurality of steps and a second step structure 405b having a plurality of steps. The first and second step structures are opposing each other. In various embodiments, the first step structure 405a and the second step structure 405b may be symmetry. For example, the second step structure 405b may be a mirror image of the first step structure 405a across line C-C′ (i.e., central axis or mirror line). In various embodiment, the numbers of the steps may be greater than two, depending on various factors, such as but not limited to, the height of the step topography of a substrate, the steepness (e.g., reclining or inclining angle) of the step topography, the linewidth of a final feature (e.g., polysilicon line, metal line, oxide etc.), types of photoresist and exposure wavelength. Similarly, the height t and length l of each step may be any arbitrary numbers, depending on the aforementioned various factors.

In various embodiments, the first step structure 405a may include an uppermost horizontal portion and a lowest most horizontal portion. The lowest most horizontal portion may be located to the left and the right of the uppermost horizontal portion, as shown in the plan view 400a. In various embodiments, the uppermost horizontal portion is connected to the lowest most horizontal portion on the left via a plurality of steps in a descending manner. Similarly, the uppermost horizontal portion is also connected to the lowest most horizontal portion on the right via a plurality of steps in a descending manner.

The second step structure 405b, which is the mirror image of the first step structure 405a, may also include an uppermost horizontal portion and a lowest most horizontal portion. The lowest most horizontal portion may be located to the left and the right of the uppermost horizontal portion, as shown in the plan view 400a. In various embodiments, the uppermost horizontal portion is connected to the lowest most horizontal portion on the left via a plurality of steps in an ascending manner. Similarly, the uppermost horizontal portion is also connected to the lowest most horizontal portion on the right via a plurality of steps in an ascending manner.

The step structure 405 may include a center region and an edge region. The center region may be defined by the uppermost horizontal portions of the first and second step structures 405a and 405b. As such, the center region has a width of x3 as shown in the plan view 400a. The edge region may be defined by the lowest most horizontal portions of the first and second step structures 405a and 405b. Therefore, the edge region has a width of x2 as shown in the plan view 400a. The linewidth x1 of the base structure is smaller than the widths x2 and x3 of the step structure, and the width x3 being the largest.

In various embodiments, the feature 401 may be used to form polysilicon line 413 on a substrate 421. The step structure 405 may be configured to be arranged over a topography step 425 of the partially processed device. The length y2 of the step structure 405 may substantially be longer than the length of the topography step 425, such that the entire angular shape (i.e., formed by a top surface 425a and an edge 425c) of the topography step 425 is within the length y2. The length y2 of the step structure is shorter if the topography step 425 is a steep slope, and the length y2 of the step structure is longer if the topography step 425 is a gradual slope. In various embodiments, the center region of the step structure 405 may be configured to be arranged over the topography step 425 of the partially processed device.

Using a reticle having the feature 401 as described, pinching of the developed photoresist 413 may be prevented. The developed photoresist 413 as shown in the plan view 400b may substantially replica the shape and size of the base structure 403 of the reticle feature 401. For example, the developed photoresist 413 may have a linewidth that is substantially the same as the linewidth x1 of the feature 401 of the reticle and a length that is substantially the same as the length y1 of the feature 401 of the reticle.

Therefore, by using a reticle feature having the step-like profile (or design) as described, the effects of the thickness variations of the photoresist, and hence the reflectivity, may substantially be compensated. As a result, the fidelity of the developed photoresist 413 is may greatly be improved.

Subsequent processing (e.g., etching of the polysilicon layer 411) using the developed photoresist 413 having a good fidelity of the feature 401 may yield a device which is able to function according to the desired specifications.

For purposes of illustration, the various embodiments are described in the context of a negative photoresist. However, it should be noted that the teaching may also be applied to a positive photoresist.

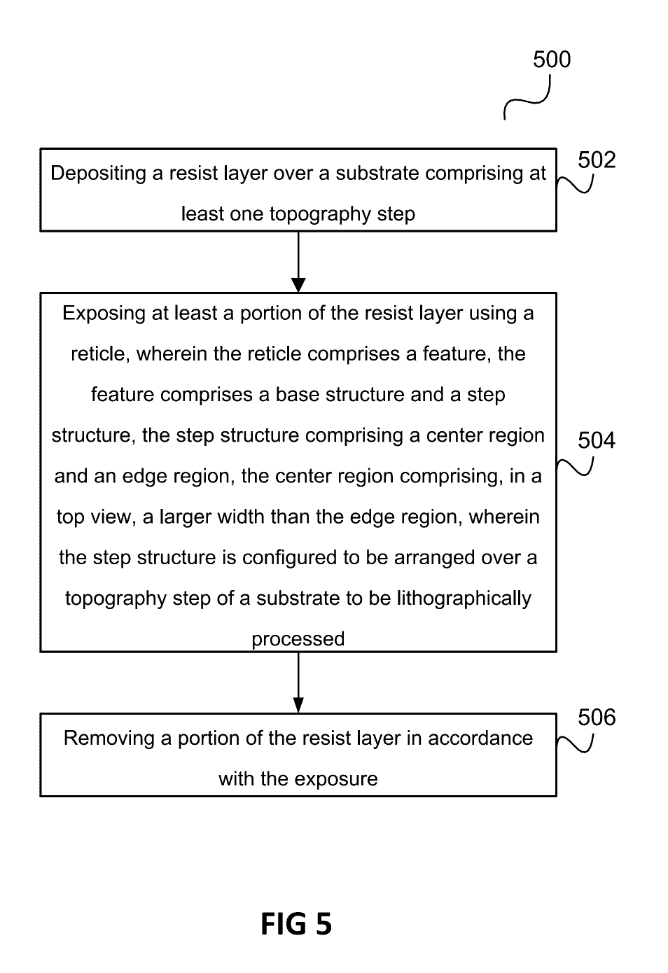

FIG. 5 shows an exemplary flow chart diagram 500 of a method of manufacturing a device in accordance with various embodiments, so that the developed photoresist and subsequently the feature produced using the developed photoresist replica the corresponding reticle feature.

At 502, a resist layer may be deposited on a substrate. The resist layer may be deposited using spin coating technology. The resist layer may be a positive or a negative photoresist. The substrate may include a topography step as shown in FIGS. 3-4.

At 504, at least a portion of the resist layer may be exposed using a reticle. The reticle may include a base structure and a step structure as shown in FIG. 4. The step structure may include a center region and an edge region. The center region may include, in a top view, a larger width than the edge region. The step structure may be configured to be arranged over a topography step of a substrate to be lithographically processed.

At 506, a portion of the resist may be removed in accordance with the exposure. For example, if a positive resist is used, the exposed portion of the resist may be removed by a developer solution. On the other hand, if a negative resist is used, the unexposed portion of the resist may be removed by a developer solution.

The pattern of the base structure (e.g., linewidth) of the reticle may be reproduced in the developed resist. The developed resist may then be used as an etch mask for forming a feature on the underlying substrate or layer.

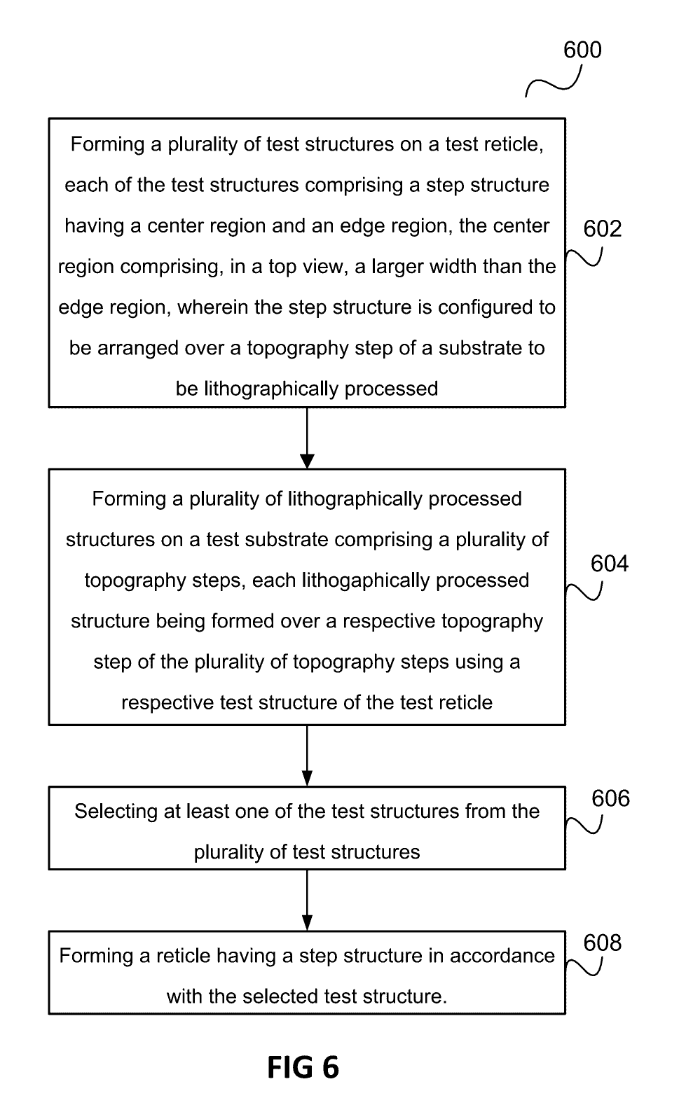

FIG. 6 shows an exemplary flow chart diagram 600 of a method of manufacturing a reticle in accordance with various embodiments.

At 602, a plurality of test structures may be formed on a test reticle. Each of the test structures may include a step structure. The step structure may include a center region and an edge region as shown in FIG. 4. The center region may include, in a top view, a larger width than the edge region. The step structure may be configured to be arranged over a topography step of a substrate to be lithographically processed.

In various embodiments, each of the step structures may be differed in the length y2, the number of steps within the same length y2, the height t of the step, the length l of step, the width x3 of the center region and the width x2 of the edge region. Other parameters may also be included in designing the step structure. In various embodiments, the step structures may be grouped into identical sets. For example, one of the sets may include a plurality of step structures, wherein each of them has a different length y2. Another set may include a plurality of step structures, wherein each of them has a different number of steps within the same length y2. Further sets are provided for other parameters, such as the height t of the step, the length l of step, the width x3 of the center region and the width x2 of the edge region.

At 604, a plurality of lithographically processed structures may be formed on a test substrate. The test substrate may include a plurality of topography steps. Each lithographically processed structure being formed over a respective topography step of the plurality of topography steps using a respective test structure of the test reticle.

In various embodiments, the test substrate may be a test wafer. Each of the plurality of the topography steps may be differed in various parameters, such as the steepness of the angular shape, the height of the topography step, the height of the isolation structure (e.g., a field oxide), linewidth of the topography step and the density of the polysilicon lines to be produced. In various embodiments, the topography steps may be grouped into sets. Each of the set may include a plurality of topography steps which are identical. For example, one of the sets may include a plurality of topography steps having the same steepness of the angular shape, another set may include a plurality of topography steps having the same height of the topography step. Further sets are provided for other parameters, such as the height of the isolation structure (e.g., a field oxide), linewidth of the topography step and the density of the polysilicon lines to be produced.

In various embodiments, the identical set of the step structures may be overlaid the set of identical topography steps to form the plurality of lithographically processed structures. For example, the set which includes a plurality of step structures, wherein each of them has a different length y2, may be overlaid the set of topography step having the same steepness of the angular shape. In such a way, the optimal length y2 may be determined.

In various embodiments, pinching values of each of the topography steps may be determined according to the various parameters. The determined pinching values may be used to analyze the inspection result which will be carried out at a later stage for selecting a test structure that produces a lithographically processed structure having the best fidelity among all the test structures.

In various embodiments, the lithographically processed structure may be a resist structure which has been formed using any suitable optical lithography systems.

At 606, at least one of the test structures may be selected from the plurality of the test structures. The selected test structure may be the one that produces a lithographically processed structure having the best fidelity among all the test structures.

At 608, a reticle having a step structure in accordance with the selected test structure may be formed.

In various embodiments, the selected test structure is added to the design data and a reticle is produced according to the selected test structure which substantially eliminates pinching effect. Such implementations are not available in the existing technology which rely on post-processing inspection (or diagnosis) of the photoresist layer or at a later stage (e.g., inspection of the etched polysilicon line). Therefore, the existing technology can be costly if a new reticle has to be made because the existing reticle is not able to produce a polysilicon layer having linewidth that meets the desired operating specifications. In contrast, the various embodiments as described herein are capable of reducing production time and costs of making the reticle (or mask).

A reticle in accordance with an embodiment may include a feature. The feature may include a base structure; and a step structure having a center region and an edge region. The center region may include, in a top view, a larger width than the edge region. The step structure may be configured to be arranged over a topography step of a substrate to be lithographically processed.

In an example of this embodiment, the feature may include a central axis along the first length.

In a further example of this embodiment, the base structure may include a uniform linewidth along the first length.

In a further example of this embodiment, wherein the step structure may include a plurality of steps along a second length, wherein the second length is shorter than the first length.

In a further example of this embodiment, the step structure may include a first step structure having a plurality of steps and a second step structure having a plurality of steps, and wherein the first and second step structures are opposing each other.

In a further example of this embodiment, the first step structure and the second step structure may be symmetry.

In a further example of this embodiment, the second step structure may be a mirror image of the first step structure across the central axis.

In a further example of this embodiment, each of the steps may include a height and a length.

In a further example of this embodiment, the first step structure may include an uppermost horizontal portion and a lowest most horizontal portion, wherein the lowest most horizontal portion is located to the left and the right of the uppermost horizontal portion; and the second step structure may include an uppermost horizontal portion and a lowest most horizontal portion, wherein the lowest most horizontal portion is located to the left and the right of the uppermost horizontal portion.

In a further example of this embodiment, for the first step structure, the uppermost horizontal portion is connected to the lowest most horizontal portion on the left via a plurality of steps in a descending manner, and wherein the uppermost horizontal portion is connected to the lowest most horizontal portion on the right via a plurality of steps in a descending manner; and for the second step structure, the uppermost horizontal portion is connected to the lowest most horizontal portion on the left via a plurality of steps in an ascending manner, and wherein the uppermost horizontal portion is connected to the lowest most horizontal portion on the right via a plurality of steps in an ascending manner.

In a further example of this embodiment, the edge region may include a first width and is defined by the lowest most horizontal portions of the first and second step structures, and wherein the center region may include a second width and is defined by the uppermost horizontal portions of the first and second step structures.

In a further example of this embodiment, the base structure may include a linewidth, wherein the linewidth is smaller than the first width and the second width, and the first width is smaller than the second width.

In a further example of this embodiment, the second length is substantially longer than a length of the topography step.

In a further example of this embodiment, the second length of the step structure is dependent on the steepness of the topography step, the height of the topography step, the linewidth of an intended feature on the substrate, the types of photoresist, exposure wavelength of a lithography system or a combination thereof.

In a further example of this embodiment, the number of the steps is dependent on the steepness of the topography step, the height of the topography step, the linewidth of an intended feature on the substrate, the types of photoresist, exposure wavelength of a lithography system or a combination thereof.

In a further example of this embodiment, the height and length of each step is dependent on the steepness of the topography step, the height of the topography step, the linewidth of an intended feature on the substrate, the types of photoresist, exposure wavelength of a lithography system or a combination thereof.

A method of manufacturing a device in accordance with an embodiment may include: depositing a resist layer over a substrate including at least one topography step; exposing at least a portion of the resist layer using a reticle, the reticle may include a feature, the feature may include a base structure and a step structure having a center region and an edge region, the center region may include, in a top view, a larger width than the edge region, the step structure may be configured to be arranged over a topography step of a substrate to be lithographically processed; and removing a portion of the resist layer in accordance with the exposure.

In an example of this embodiment, the resist layer is a negative photoresist or a positive photoresist.

A method of manufacturing a reticle in accordance with an embodiment may include: forming a plurality of plurality of test structures on a test reticle, each of the test structures may include a step structure having a center region and an edge region, the center region may include, in a top view, a larger width than the edge region, wherein the step structure is configured to be arranged over a topography step of a substrate to be lithographically processed; forming a plurality of lithographically processed structures on a test substrate including a plurality of topography steps, each lithographically processed structure being formed over a respective topography step of the plurality of topography steps using a respective test structure of the test reticle; selecting at least one of the test structures from the plurality of test structures; and forming a reticle having a step structure in accordance with the selected test structure.

In an example of this embodiment, each of the step structure is different in length, number of steps with the same length, step height, step length, width of the central region and width of the edge region.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A reticle, comprising:
a feature, wherein the feature comprises:
a base structure; and
a step structure comprising a center region and an edge region, the center region comprising, in a top view, a larger width than the edge region, wherein the step structure is configured to be arranged over a topography step of a substrate to be lithographically processed.

2. The reticle of claim 1,
wherein the feature comprises a central axis along the first length.

3. The reticle of claim 2,
wherein the base structure comprises a uniform linewidth along the first length.

4. The reticle of claim 2,
wherein the step structure comprises a plurality of steps along a second length, wherein the second length is shorter than the first length.

5. The reticle of claim 4,
wherein the step structure comprises a first step structure having a plurality of steps and a second step structure having a plurality of steps, and wherein the first and second step structures are opposing each other.

6. The reticle of claim 5,
wherein the first step structure and the second step structure are symmetry.

7. The reticle of claim 5,
wherein the second step structure is a mirror image of the first step structure across the central axis.

8. The reticle of claim 5,
wherein each of the steps comprises a height and a length.

9. The reticle of claim 5,
wherein the first step structure comprises an uppermost horizontal portion and a lowest most horizontal portion, wherein the lowest most horizontal portion is located to the left and the right of the uppermost horizontal portion; and
wherein the second step structure comprises an uppermost horizontal portion and a lowest most horizontal portion, wherein the lowest most horizontal portion is located to the left and the right of the uppermost horizontal portion.

10. The reticle of claim 9,
wherein for the first step structure, the uppermost horizontal portion is connected to the lowest most horizontal portion on the left via a plurality of steps in a descending manner, and wherein the uppermost horizontal portion is connected to the lowest most horizontal portion on the right via a plurality of steps in a descending manner; and
wherein for the second step structure, the uppermost horizontal portion is connected to the lowest most horizontal portion on the left via a plurality of steps in an ascending manner, and wherein the uppermost horizontal portion is connected to the lowest most horizontal portion on the right via a plurality of steps in an ascending manner.

11. The reticle of claim 9,
wherein the edge region comprises a first width and is defined by the lowest most horizontal portions of the first and second step structures, and wherein the center region comprises a second width and is defined by the uppermost horizontal portions of the first and second step structures.

12. The reticle of claim 11,
wherein the base structure comprises a linewidth, wherein the linewidth is smaller than the first width and the second width, and the first width is smaller than the second width.

13. The reticle of claim 4,
wherein the second length is substantially longer than a length of the topography step.

14. The reticle of claim 13,
wherein the second length of the step structure is dependent on the steepness of the topography step, the height of the topography step, the linewidth of an intended feature on the substrate, the types of photoresist, exposure wavelength of a lithography system or a combination thereof.

15. The reticle of claim 4,
wherein the number of the steps is dependent on the steepness of the topography step, the height of the topography step, the linewidth of an intended feature on the substrate, the types of photoresist, exposure wavelength of a lithography system or a combination thereof.

16. The reticle of claim 8,
wherein the height and length of each step is dependent on the steepness of the topography step, the height of the topography step, the linewidth of an intended feature on the substrate, the types of photoresist, exposure wavelength of a lithography system or a combination thereof.

17. A method of manufacturing a device, the method comprising:
depositing a resist layer over a substrate comprising at least one topography step;
exposing at least a portion of the resist layer using a reticle, the reticle, comprising:
a feature, wherein the feature comprises:
a base structure; and
a step structure comprising a center region and an edge region, the center region comprising, in a top view, a larger width than the edge region, wherein the step structure is configured to be arranged over a topography step of a substrate to be lithographically processed;
removing a portion of the resist layer in accordance with the exposure.

18. The method of claim 17,
wherein the resist layer is a negative photoresist or a positive photoresist.

19. A method of manufacturing a reticle, the method comprising:
forming a plurality of plurality of test structures on a test reticle, each of the test structures comprising a step structure having a center region and an edge region, the center region comprising, in a top view, a larger width than the edge region, wherein the step structure is configured to be arranged over a topography step of a substrate to be lithographically processed;
forming a plurality of lithographically processed structures on a test substrate comprising a plurality of topography steps, each lithographically processed structure being formed over a respective topography step of the plurality of topography steps using a respective test structure of the test reticle;
selecting at least one of the test structures from the plurality of test structures; and
forming a reticle comprising a step structure in accordance with the selected test structure.

20. The method of claim 19,
wherein each of the step structure is different in length, number of steps with the same length, step height, step length, width of the central region and width of the edge region.
